(19) United States
(12) Patent Application Publication
(10) Pub. No.: US 2012/0293952 A1
(43) Pub. Date: Nov. 22, 2012

(54) HEAT TRANSFER APPARATUS

(75) Inventors: Dean F. Herring, Youngsville, NC (US); Jason A. Matteson, Raleigh, NC (US); Paul A. Wormsbecher, Apex, NC (US)

(73) Assignee: INTERNATIONAL BUSINESS MACHINES CORPORATION, Armonk, NY (US)

(21) Appl. No.: 13/111,553

(22) Filed: May 19, 2011

(51) Int. Cl. H05K 7/20

(52) U.S. Cl. 361/679.54; 361/704; 361/694; 361/692

(57) ABSTRACT

An apparatus is provided to remove heat from a heat-generating component of a computer, such as a processor. The apparatus comprises a first heat sink having a plurality of leader fins, wherein the first heat sink is thermo-conductively coupled to a heat-generating component that is coupled to a first portion of a chassis; and a second heat sink having a plurality of follower fins, wherein the second heat sink is thermo-conductively coupled to a second portion of the chassis, and wherein the plurality of follower fins are disposed in an interlaced configuration with the plurality of follower fins to promote radiative heat transfer from the leader fins to the follower fins. Optionally, one or more alignment structures may be used to facilitate the relative movement of the first and second chassis portions into an operative position in which the leader and follower fins are in the interlaced configuration. The apparatus may be used to remove heat from a heat-generating component in a closed system with little or no limited air flow.

### BACKGROUND

1. Field of the Invention

The present invention relates generally to systems that remove heat generated within computer systems, and more specifically to heat sinks that draw heat away from a heat-generating device such as, for example, a CPU.

2. Background of the Related Art

Computers generally include heat-generating components that consume electrical current and generate heat in an operative mode. For example, but not by way of limitation, central processing units (CPUs), chipsets, graphics cards and hard drives consume electrical current and generate heat during operation. A CPU may comprise thousands or even millions of circuit elements disposed within a square centimeter so that the heat generation density is very high. This heat must be removed from the electrical component in order to maintain performance, prevent unwanted material degradation and to prevent premature failure of the component. Insufficient heat removal from a heat-generating electrical component may also result in generally unsatisfactory computer performance.

Heat-generating components of a computer may be cooled by convective heat transfer; that is, a heat generating component may transfer generated heat to the air surrounding the heat generating component. Conductive fins may be thermo-conductively coupled to a heat-generating device to substantially increase the surface area across which convective heat transfer to surrounding air may occur. An air mover, such as a fan, may provide a steady supply of cooling air flow across the fins to further improve heat transfer from the heat-generating device. For example, a fan may be attached to a computer chassis to force or draw air flow across a heat generating device or across fins thermo-conductively coupled to a heat generating device. Heat-generating components of a computer may also be cooled using a liquid coolant moved by a pump to provide a steady supply of cooling liquid flow through a heat exchanger in thermal communication with the heat-generating device.

In a closed system, a heat-generating device may be substantially enclosed and/or isolated from sources of cooling air flow. As a result, convective heat removal may be insufficient or unavailable in some chassis. A heat-generating component within a closed system or otherwise not positioned for exposure to cooling air flow may rely upon other less-efficient heat transfer modes such as, for example, radiative heat transfer.

### BRIEF SUMMARY

One embodiment of the present invention provides an apparatus comprising a first heat sink having a plurality of leader fins, wherein the first heat sink is thermo-conductively coupled to a heat-generating component that is coupled to a first portion of a chassis. The apparatus further comprises a second heat sink having a plurality of follower fins, wherein the second heat sink is thermo-conductively coupled to a second portion of the chassis, and wherein the plurality of follower fins are disposed in an interlaced configuration with the plurality of follower fins to promote radiative heat transfer from the leader fins to the follower fins.

### BRIEF DESCRIPTION OF THE SEVERAL VIEWS OF THE DRAWINGS

FIG. 1 is a side elevation view of an apparatus to facilitate radiative heat transfer in an operative mode when disposed between a first heat sink thermo-conductively coupled to a CPU and a second heat sink thermo-conductively coupled to a portion of a chassis.

FIG. 2 is an end elevation view of the apparatus of FIG. 1.

FIG. 3 is the side elevation view of FIG. 1 after moving a portion of the heat transfer apparatus to an inoperative position.

FIG. 4 is a side elevation view of the apparatus of FIG. 1 with the addition of a chassis heat sink on the exterior of the chassis in a position opposite the second heat sink.

FIG. 5 is a side elevation view of an apparatus having a plurality of fins that extend through the chassis.

FIG. 6 is a flowchart of a method of removing heat from a processor using an apparatus such as that illustrated in FIGS. 1 and 2.

### DETAILED DESCRIPTION

Various embodiments of the present invention are directed to an apparatus that facilitates passive heat transfer from a first heat sink thermo-conductively coupled to the heat generating component to a second heat sink thermo-conductively coupled to an opposing portion of a chassis. The first heat sink has a plurality of fins, referred to herein as “leader fins,” thermo-conductively coupled to the heat-generating electronic component. The second heat sink also has a plurality of fins, referred to herein as “follower fins,” thermo-conductively coupled to a portion of the computer chassis. The follower fins are interlaced, in an operative position, with the plurality of leader fins to facilitate radiative heat transfer from the plurality of leader fins to the plurality of follower fins. In addition to radiative heat transfer, the apparatus is capable of supporting heat transfer from the first heat sink to the second heat sink through natural convection. Although the apparatus may be used in combination with an air mover to provide forced convection, the apparatus is particularly well-suited to implementations where forced convection is not possible or practical. Where an air mover is available, it is preferably used to provide air flow over the follower fins of the second heat sink or the fins of the chassis heat sink.

In a preferred embodiment, each leader fin is generally parallel one to the others, each follower fin is generally parallel one to the others, and the plurality of leader fins are interlaced with the plurality of follower fins so that each leader fin is generally parallel to each adjacent follower fin to maximize the collective surface area of the leader fins from which radiation is emitted and to maximize the collective surface area of the follower fins into which radiation emitted from the plurality of leader fins is absorbed. Alternatively, a heat transfer junction may be formed using first and second heat sinks having concentric fins or plates instead of parallel fins. Furthermore, it should be recognized that any of fin configurations described herein, could be used with the fins immersed in a thermal transfer fluid, such as captive gas or liquid. A sealed chamber around the fins of the first and second heat sinks may be used to retain the thermal transfer fluid in place.

In one embodiment, the first chassis portion is movable relative to the second chassis portion, such that the plurality of leader fins of the first heat sink may be selectively interlaced with the plurality of follower fins of the second heat sink. Such relative movement of the first and second chassis portions may be necessary to facilitate access to components within the chassis. For example, but not by way of limitation, the first heat sink may be thermo-conductively coupled to a heat generating device, such as processor installed on a mother board that is secured within the computer chassis. Furthermore, the second heat sink may be connected to a chassis portion that is movable relative to the mother board.

The plurality of follower fins may be moved to the operative (interlaced) configuration with the plurality of leader fins by use of one or more alignment structures. An alignment structure may comprise, for example, but not by way of limitation, one or more post on the first chassis portion slidably receivable within apertures or recesses on a second chassis portion, a tongue on the first chassis portion receivable within a groove or slot on the second chassis portion, or some combination of these. A plurality of such alignment structures may be used to enhance alignment and to direct movement of the plurality of follower fins to the interlaced configuration with the leader fins. The type or number of alignment structures may depend on the dimensions, thickness and/or pitch (separation) of adjacent leader fins and/or follower fins. An alternate alignment structure may be a hinge coupled on a first side to the first chassis portion and on a second side to the second chassis portion to constrain the movement of the chassis portion to pivot about an axis relative to the second chassis portion.

In one embodiment, the first heat sink may be integral with the heat generating component, such as a processor. In a similar, but independent, embodiment, the second heat sink may be integral with the second chassis portion. For example, but not by way of limitation, the second chassis portion may from a second heat sink comprising a plurality of integrally-formed follower fins extending therefrom. Whether the first heat sink and/or the second heat sink are discrete components or integral to the processor or chassis, the plurality of leader fins of the first heat sink are disposed in an interlaced position with the plurality of follower fins of the second heat sink. In this configuration, the plurality of leader fins and the plurality of follower fins may be said to be parts of a heat transfer junction.

In one embodiment, a second heat sink and/or a chassis portion to which the second heat sink is thermo-conductively coupled may comprise one or more structures such as, for example, one or more ventilation slots, to facilitate convective cooling of the second heat sink and/or chassis portion. For example, but not by way of limitation, a plurality of ventilation slots may be disposed on the second heat sink and between adjacent follower fins. In another embodiment, a plurality of chassis fins may be disposed on the second chassis portion to promote cooling of the second chassis portion to the environment external to the chassis.

In one embodiment of the apparatus, the plurality of follower fins and the plurality of leader fins may be made from, or include, dissimilar materials to promote radiative heat transfer from the plurality of leader fins to the plurality of follower fins. For example, but not by way of limitation, the leader fins may comprise aluminum or aluminum alloy to promote emissivity and the plurality of follower fins may comprise copper or a copper alloy to promote absorbance.

In one embodiment of the apparatus, the plurality of leader fins may be treated and/or coated to increase emissivity and thereby promote radiative heat transfer from the plurality of leader fins to the plurality of follower fins. In one embodiment of the apparatus, the plurality of follower fins may be treated and/or coated to increase absorbance to promote radiative heat transfer to the plurality of follower fins from the plurality of leader fins. This can sometimes be accomplished using the same coating on both the leader and follower fins. Examples of suitable coatings include zinc oxide, gold, or a “black” body coating, such as a transmissive carbon black coating, a carbon nanotube based coating.

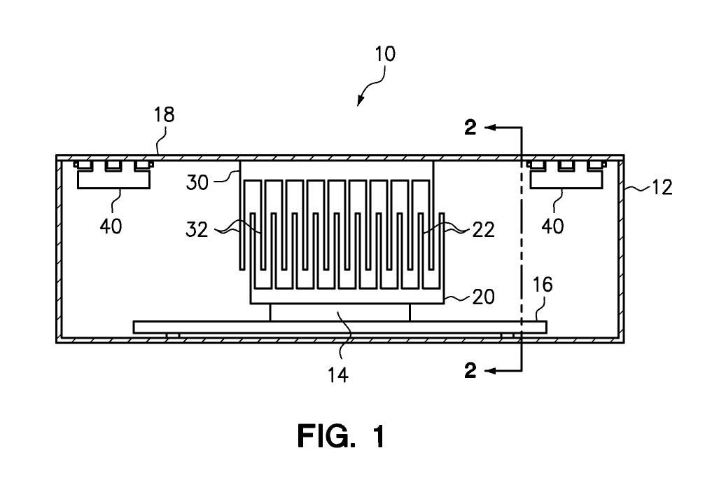

FIG. 1 is a side elevation view of one embodiment of a computer system 10 including a chassis 12 that houses various computer components. A heat-generating electronic component, such as a central processing unit (CPU) 14, is thermo-conductively coupled to a first heat sink 20 and a plurality of leader fins 22 extending from the first heat sink 20. The processor 14 may be installed on a motherboard or other circuit board substrate 16 that is secured to a first portion of the chassis 12.

A second heat sink 30 includes a plurality of follower fins 32. Each of the plurality of leader fins 22 is generally parallel one to the others and evenly spaced and each of the plurality of follower fins 32 is generally parallel one to the others and evenly spaced. Accordingly, the plurality of leader fins 22 and the plurality of follower fins 32 may be disposed in an interlaced configuration (as shown) to promote radiative heat transfer from the leader fins 22 to the follower fins 32 without contact therebetween.

While the first heat sink 20 is in thermo-conductive contact with the heat generating processor 14, the second heat sink 20 is thermo-conductively coupled to a second portion 18 of the chassis 12. The second chassis portion 18 may be movably coupled to the first portion of the chassis 12 through an alignment structure. For example, the second chassis portion 18 may be a lid or cover and the alignment structure may include one or more hinge 40 which pivots about an axis. As shown in FIG. 1, the cover 18 is closed with the plurality of follower fins 32 received into an interlaced configuration with the plurality of leader fins 22. The thickness, spacing and material of the leader fins 22 and the follower fins 32 may be optimized to promote radiative heat transfer across the heat transfer junction formed thereby. Natural convection may also play a role in the heat transfer across the junction.

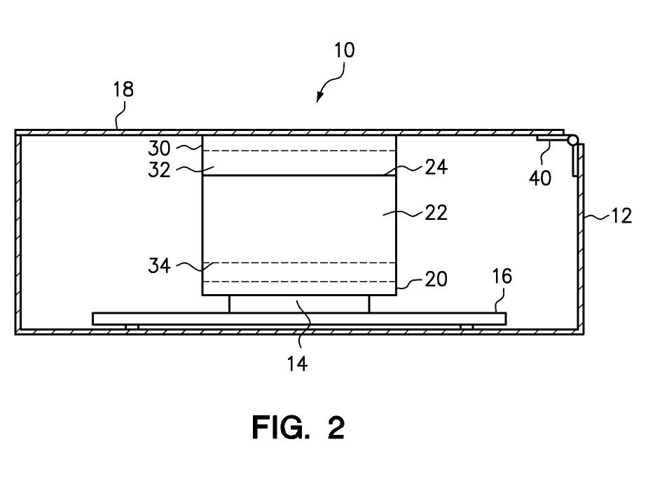

FIG. 2 is an end elevation view of the apparatus of FIG. 1 illustrating the plurality of leader fins 22 extending from the first heat sink 20, wherein the leader fins 22 are interlaced with the plurality of follower fins 32 extending from the second heat sink 30 to form a heat transfer junction that transfers a substantial portion of the heat generated by processor 14 to the second chassis portion 18. Specifically, heat passes to the first heat sink 20 including the plurality of leader fins 22, and across to the plurality of follower fins 32 of the second heat sink 20. The width-to-length ratio of the leader fins 22 and the follower fins 32 (a portion of which is obscured by leader fin 22 in FIG. 2) illustrated in FIG. 2 may be optimized to promote radiative heat transfer across the heat transfer junction formed thereby. From the view shown, the end 24 of one leader fin 22 can be directly seen, whereas the end 34 of the adjacent follower fin 32 is hidden behind the leader fin 22.

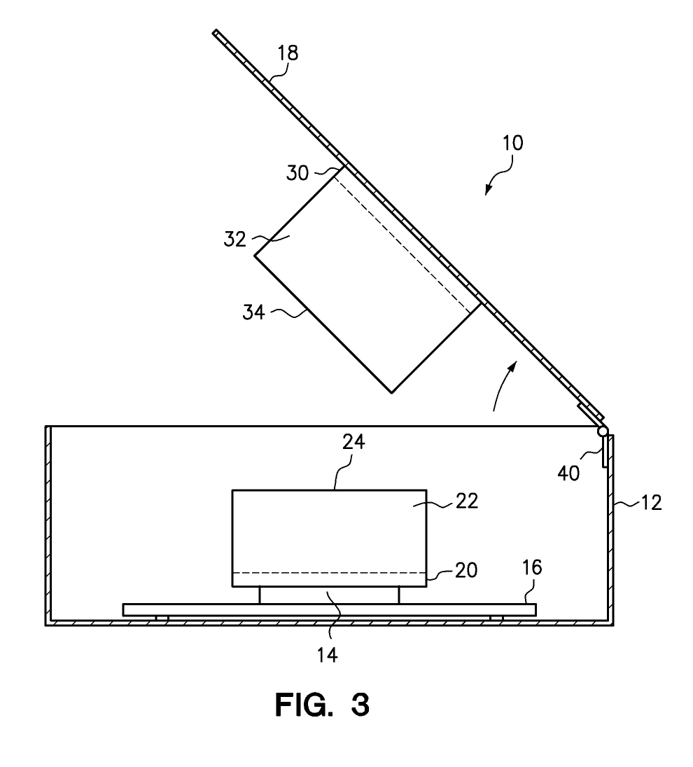

FIG. 3 is the end elevation view of the apparatus of FIG. 2 after the hinge 40 has been used to pivot the second chassis portion 18 to an open position allowing user access to components within the chassis 12. Accordingly, the plurality of follower fins 32 are no longer disposed in the interlaced configuration with the plurality of leader fins 22 as was illustrated in FIGS. 1 and 2. Rather, the follower fins and the leader fins are in an inoperative configuration in FIG. 3. It will be understood that alternative alignment structures may be employed in place of or in addition to the hinge 40 illustrated in FIG. 3. For example, but not by way of limitation, the second chassis portion 18 may be docked with the first portion of the chassis 12 to place the follower fins 32 in the interlaced configuration with the leader fins 22 using one or more posts disposed on one of the first chassis portion 18 and the second portion of the chassis 12 with such posts receivable within one or more tapered apertures on the other of the first chassis portion 18 and the second portion of the chassis 12. It will be understood that the positioning and the type of alignment structures may be selected to accommodate the configuration of the leaders fins 22 and the follower fins 32, and/or the overlap between them when in the interlaced configuration as illustrated in FIG. 1.

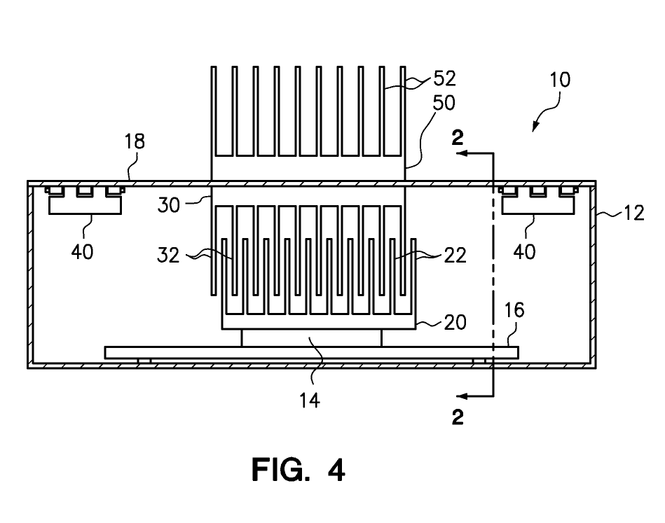

FIG. 4 is a side elevation view of the apparatus 10 of FIG. 1 with the addition of a chassis heat sink 50 on the exterior of the chassis 12 in a position opposite the second heat sink 30. While the second heat sink 30 takes on heat from the first heat sink 20 and passes that heat to the second chassis portion 18, the chassis heat sink 50 takes heat from the second chassis portion 18 and spreads it out over a plurality of fins 52. Accordingly, the heat in the fins 52 may be passed into the surrounding environment via radiation, convection or both. In some environments, there will be forced air movement across the chassis heat sink 50 while there may not be any forced air movement within the chassis 12.

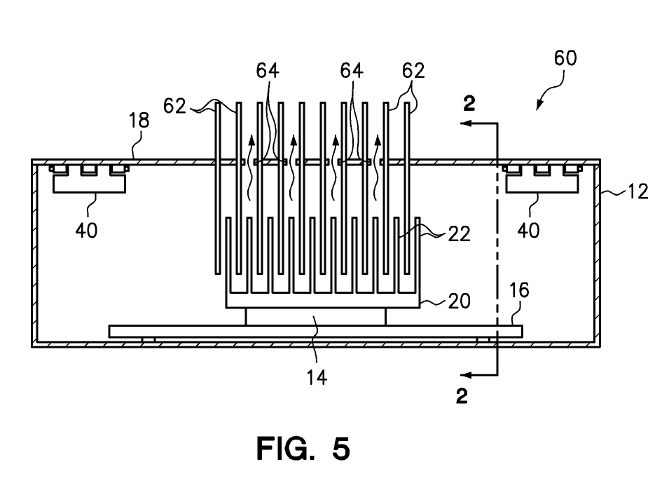

FIG. 5 is a side elevation view of an apparatus 60 that is similar to the apparatus 10 of FIG. 1, but has a plurality of fins 62 that extend through the second chassis portion 18. Specifically, a first end of each fin 62 is on the interior of the second chassis portion 18 and is interlaced with the finds 22 of the first heat sink 20. A second end of each fin 62 is on the exterior of the second chassis portion 18 for dissipation of heat into the environment. This is just one construction that is an alternative to the separate opposing heat sinks 30, 50 in FIG. 4. Still further, the apparatus 60 in FIG. 5 includes one embodiment of optional vents 64 that allow for warm air to leave the chassis. Cooler air may enter the chassis through over vents or gaps in the chassis 12, such as around the edges of the second chassis portion 18.

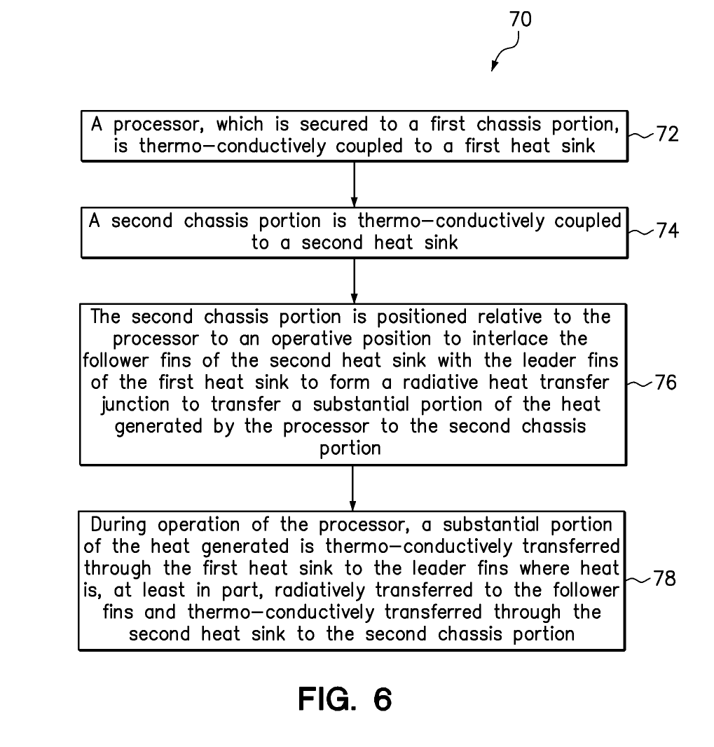

FIG. 6 is a flowchart illustrating the steps of an embodiment of a method 70 of removing heat from a processor using an apparatus, such as the heat transfer junction illustrated in FIGS. 1 and 2. In step 72, a processor (14), which is secured to a first chassis portion (12), is thermo-conductively coupled to a first heat sink (20) having a plurality of leader fins (22) extending therefrom with the leader fins (22) generally parallel one to the others. In step 74, a second chassis portion (18) is thermo-conductively coupled to a second heat sink (30) having a plurality of follower fins (32) extending therefrom with the follower fins (32) generally parallel one to the others. In step 76, the second chassis portion (18) is positioned relative to the processor (14) to an operative position to interlace the follower fins (32) with the plurality of leader fins (22) to form a heat transfer junction that transfers a substantial portion of the heat generated by the processor (14) to the second chassis portion (18). In step 78, the processor (14) is electronically activated and generates heat, a substantial portion of which is thermo-conductively transferred through the first heat sink (20) to the leader fins (22) where it is, at least in part, radiatively transferred to the follower fins (32) and thermo-conductively transferred to through the second heat sink (30) to the second chassis portion 18.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed.

Many modifications and variations will be apparent to those of ordinary skill in the art without departing from the scope and spirit of the invention. The embodiment illustrated in the appended figures is chosen and described to best explain the principles of the invention and the practical application, and to enable others having ordinary skill in the art to understand the invention for various embodiments with various modifications as are suited to the particular use contemplated.

What is claimed is:

1. An apparatus comprising:
a first heat sink having a plurality of leader fins, wherein the first heat sink is thermo-conductively coupled to a heat-generating component that is coupled to a first portion of a chassis; and
a second heat sink having a plurality of follower fins, wherein the second heat sink is thermo-conductively coupled to a second portion of the chassis;
wherein the plurality of follower fins are disposed in an interlaced configuration with the plurality of follower fins to promote radiative heat transfer from the leader fins to the follower fins.

2. The apparatus of claim 1, wherein the second chassis portion is movable relative to the first chassis portion.

3. The apparatus of claim 2, further comprising:
an alignment structure on at least one of the first chassis portion and the second chassis portion to facilitate movement of the first chassis portion to an operative position with the second chassis portion.

4. The apparatus of claim 1, wherein the second chassis portion is movable relative to the first chassis portion from an operative position to an inoperative position to remove the plurality of follower fins from the interlaced configuration with the plurality of leader fins.

5. The apparatus of claim 1, wherein a substantial portion of heat generated in the heat-generating electronic component is removed to the second chassis portion by radiative heat transfer from the plurality of leader fins to the plurality of follower fins.

6. The apparatus of claim 1, wherein the plurality of leader fins are integral with the first heat sink.

7. The apparatus of claim 1, wherein the plurality of leader fins are black to promote radiative emissivity.

8. The apparatus of claim 1, wherein the plurality of leader fins comprise a coating to provide a radiative emissivity coefficient of at least 0.9.

9. The apparatus of claim 1, wherein the plurality of leader fins comprise a material having a radiative emissivity coefficient of at least 0.9.

10. The apparatus of claim 1, wherein the plurality of follower fins are integral with the second heat sink.

11. The apparatus of claim 1, wherein the plurality of follower fins are coated to promote radiative absorptivity.

12. The apparatus of claim 1, wherein the plurality of follower fins are black to provide a radiative absorptivity coefficient of at least 0.9.

13. The apparatus of claim 1, wherein the plurality of follower fins comprise a material having a radiative absorptivity coefficient of at least 0.9.

14. The apparatus of claim 1, wherein the heat-generating electronic component comprises a substrate connected to the first portion of the chassis.

15. The apparatus of claim 1, wherein the heat-generating electronic component is a central processing unit.

16. The apparatus of claim 1, wherein the second chassis portion comprises a plurality of chassis fins thermo-conductively coupled to the second heat sink and extending opposite of the second chassis portion from the second heat sink.

17. The apparatus of claim 1, wherein the heat-generating electronic component is disposed within a closed chassis substantially isolating the heat-generating electronic component from cooling air flow.

18. The apparatus of claim 1, further comprising:
an air mover to move air across the plurality of follower fins.

19. The apparatus of claim 1, further comprising:
at least one guide structure coupled to at least one of the plurality of leader fins and the plurality of follower fins to guide the plurality of follower fins to the interlaced configuration with the plurality of leader fins.

20. The apparatus of claim 1, further comprising:
one or more vents disposed on at least one of the second heat sink and the second chassis portion.
